(19) United States
(12) Patent Application Publication
(10) Pub. No.: US 2026/0231608 A1
(43) Pub. Date: Aug. 6, 2026

(54) DISPLAY APPARATUS, METHOD OF MANUFACTURING DISPLAY APPARATUS AND ELECTRONIC DEVICE INCLUDING DISPLAY APPARATUS

(71) Applicant: Samsung Display Co., Ltd., Yongin-si (KR)

(72) Inventors: Taehyun Hong, Yongin-si (KR); Myounggeun Cha, Yongin-si (KR); Meejae Kang, Yongin-si (KR); Hanbit Kim, Yongin-si (KR); Yunjung Oh, Yongin-si (KR); Kiseok Choi, Yongin-si (KR)

(21) Appl. No.: 19/459,776

(22) Filed: Jan. 26, 2026

(30) Foreign Application Priority Data
Jan. 31, 2025 (KR) 10-2025-0012637

(51) Int. Cl. H10K 59/12; H10K 59/123

(52) U.S. Cl. CPC H10K 59/1201; H10K 59/123

(57) ABSTRACT

A method of manufacturing a display apparatus (e.g., a high-resolution display apparatus) and a display apparatus (e.g., a high-resolution display apparatus) manufactured by the method are disclosed. The method may include forming or arranging a thin film transistor layer on a substrate, including a semiconductor layer and a first insulating (e.g., electrically insulating) layer with a through hole. A first metal layer may be formed or arranged, covering the through hole's inner surface and semiconductor layer top surface. A selection layer may be applied, with regions selectively removed. A self-assembled monolayer may be formed or arranged on a specific (e.g., set or predetermined) region, and a filling material may be added to a defined groove. The self-assembled monolayer and selection region may be partially removed, and a second metal layer may be deposited on the first metal layer and filling material, enabling ultra-high resolution screen implementation.

### CROSS-REFERENCE TO RELATED APPLICATION

The present application claims priority to and the benefit of Korean Patent Application No. 10-2025-0012637, filed on January 31, 2025, in the Korean Intellectual Property Office, the entire disclosure of which is incorporated herein by reference.

### BACKGROUND

### 1. Field

One or more embodiments of the present disclosure relate to a display apparatus, a method of manufacturing the display apparatus, and an electronic device including the display apparatus. For example, one or more embodiments of the present disclosure relate to a display apparatus in which an ultra-high resolution screen is implemented, a method of manufacturing the display apparatus, and an electronic device including the display apparatus.

### 2. Description of the Related Art

Display apparatuses are designed to receive information about an image and display the image. These display apparatuses may be utilized as display components in small electronic products, such as mobile phones, as well as in larger electronic products, such as televisions.

Display apparatuses include a plurality of pixels that emit light upon receiving electrical signals, thereby displaying images externally. Each pixel includes a light-emitting element, for example, in organic light-emitting display apparatuses, the pixel may include an organic light-emitting diode (OLED) as the light-emitting element. Typically, display apparatuses incorporate a thin film transistor and an OLED on a substrate.

Additionally, electronic devices may provide a visual interface that meets the needs or desires of users through these display apparatuses.

### SUMMARY

One or more aspects of embodiments of the present disclosure are directed toward a display apparatus in which an ultra-high resolution screen may be implemented, a method of manufacturing the display apparatus, and an electronic device including the display apparatus. However, these embodiments are provided as examples only, and the scope of the present disclosure should not be limited thereby.

Additional aspects of embodiments will be set forth in part in the description which follows and, in part, will be apparent from the description or may be learned by practice of the presented embodiments of the disclosure.

According to one or more embodiments, a method of manufacturing a display apparatus may include forming or arranging a semiconductor layer and a first insulating (e.g., electrically insulating) layer on the semiconductor layer on a substrate, wherein the first insulating layer has (or includes) a first through hole exposing a top surface of the semiconductor layer upward, forming or arranging a first metal layer including a first portion covering an inner side surface of the first through hole and the top surface of the semiconductor layer, and a second portion covering a top surface of the first insulating layer, forming or arranging a selection layer including a first region covering the first portion and a second region covering the second portion, removing the first region of the selection layer, forming or arranging a self-assembled monolayer on the second region of the selection layer, forming or arranging a filling material in a groove defined by the second region, removing the self-assembled monolayer and at least a portion of the second region, and forming or arranging a second metal layer on the first metal layer and the filling material.

A thickness of the second region may be greater than a thickness of the first region.

The removing of the first region may utilize a dry etching process.

The dry etching process may be applied to the first region and the second region concurrently (e.g., simultaneously).

The thickness of the second region before applying the dry etching process may be thicker than the thickness of the second region after applying the dry etching process.

The forming or arranging of the filling material in the groove defined by the second portion may utilize an atomic layer deposition (ALD) process.

The selection layer may include an insulating (e.g., electrically insulating) material.

After the second region (e.g., a portion of the second region) is removed, the first metal layer may directly contact the second metal layer.

The selection layer may include a conductive (e.g., electrically conductive) material.

The removing of the at least a portion of the self-assembled monolayer and the second region may remove only a portion of the second region. In one or more embodiments, in the removing of the self-assembled monolayer and the at least a portion the second region, only a portion of the second region may be removed.

The method of manufacturing a display apparatus according to one or more embodiments may further include forming or arranging a second insulating (e.g., electrically insulating) layer on the second metal layer, and the second insulating layer may have (or include) a second through hole overlapping with the first through hole in plan view.

The method of manufacturing a display apparatus according to one or more embodiments may further include forming or arranging a third metal layer on the second insulating layer.

The forming or arranging of the filling material in the groove defined by the second region may include forming or arranging an organic film on the first metal layer, and removing a portion of the organic film on the second portion.

An amount of carbon contained in the filling material may be less than 1%.

According to one or more embodiments, a method of manufacturing a display apparatus according to one or more embodiments may include forming or arranging a semiconductor layer and a first insulating (e.g., electrically insulating) layer on the semiconductor layer on a substrate, wherein the first insulating layer includes a first through hole exposing a top surface of the semiconductor layer upward, forming or arranging a first metal layer including a first portion covering an inner side surface of the first through hole and the top surface of the semiconductor layer, and a second portion covering the top surface of the semiconductor layer, forming or arranging an insulating (e.g., electrically insulating) material layer covering the first portion and the second portion utilizing an ALD process, planarizing a top surface of the insulating material layer utilizing a Chemical Mechanical Polishing (CMP) process, and forming or arranging a second metal layer on the insulating material layer.

The method of manufacturing a display apparatus according to one or more embodiments may further include forming or arranging a second insulating (e.g., electrically insulating) layer having (or including) a second through hole overlapping with the first through hole in plan view on the second metal layer.

The method of manufacturing a display apparatus according to one or more embodiments may further include forming or arranging a third metal layer on the second insulating layer.

An amount of carbon contained in the insulating material layer may be less than 1%.

According to one or more embodiments, a display apparatus according to one or more embodiments may be manufactured by a manufacturing method according to one or more embodiments as described herein.

According to one or more embodiments, an electronic device according to one or more embodiments may include a memory that is to store data information, a processor that is to generate a data signal and/or a control signal based on the data information, and a display apparatus that is to operate based on the data signal and/or the control signal and may be manufactured by a manufacturing method according to one or more embodiments as described herein.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a plan view schematically illustrating a display apparatus according to one or more embodiments;

FIG. 2 is an example of an equivalent circuit diagram schematically illustrating a sub-pixel of the display apparatus of FIG. 1;

FIGS. 3-12 are cross-sectional views schematically illustrating a cross-section obtained along the line A-A' of FIG. 1 according to a manufacturing process sequence;

FIGS. 13-16 are cross-sectional views schematically illustrating a cross-section obtained along the line A-A' of FIG. 1 according to a manufacturing process sequence;

FIGS. 17-21 are cross-sectional views schematically illustrating a cross-section obtained along the line A-A' of FIG. 1 according to a manufacturing process sequence;

FIG. 22 is a block diagram of an electronic device according to one or more embodiments; and

FIG. 23 is a schematic diagram of electronic devices according to one or more embodiments.

### DETAILED DESCRIPTION

Reference will be made in more detail to one or more embodiments, examples of which are illustrated in the accompanying drawings, wherein like reference numerals refer to like elements throughout the attached drawings and the written description, and duplicative descriptions thereof may not be provided in the specification. In this regard, the subject matter of the present disclosure may be embodied in different forms and should not be construed as being limited to one or more embodiments set forth herein. Rather, these embodiments are provided as examples, by referring to the drawings, to explain aspects and features of the present disclosure to those skilled in the art.

The utilization of “may” if (e.g., when) describing embodiments of the present disclosure refers to “one or more embodiments of the present disclosure.”

In the context of the present application and unless otherwise defined, the terms "use," "using," and "used" may be considered synonymous with the terms "utilize," "utilizing," and "utilized," respectively.

As used herein, the term "and/or" includes any and all combinations of one or more of the associated listed items. For example, "A and/or B" indicates cases where it is A, or B, or both (e.g., simultaneously) A and B.

Throughout the present disclosure, the expression "at least one of a, b, or c" indicates only a, only b, only c, both (e.g., simultaneously) a and b, both (e.g., simultaneously) a and c, both (e.g., simultaneously) b and c, all of a, b, and c, or variations thereof.

The present disclosure may be subject to one or more suitable modifications and may have one or more embodiments, and specific embodiments may be illustrated in the drawings and described in more detail in the detailed description. The aspects and features of the present disclosure and methods for achieving them will become more apparent by referring to one or more embodiments as described in more detail with the accompanying drawings. However, the present disclosure is not limited to one or more embodiments disclosed but may be implemented in one or more suitable forms.

Hereinafter, one or more embodiments of the present disclosure will be described in more detail with reference to the accompanying drawings, and if (e.g., when) describing with reference to the drawings, substantially the same or corresponding components are given the same reference numerals, and redundant descriptions thereof may not be provided.

In the following embodiments, terms, such as “first,” “second,” and/or the like are used not in a limiting sense but for the purpose of distinguishing one component from another component.

In the following embodiments, a singular expression includes a plural expression unless the context clearly indicates otherwise.

In the following embodiments, if (e.g., when) one or more suitable components, such as a layer, a film, a region, a plate, and/or the like, are described as being "on" another component, this includes not only the case where they are "directly on" the other component but also the case where another component is present

therebetween. In contrast, if (e.g., when) a component is referred to as being “directly on” another component, there are no intervening components present therebetween.

Also, for convenience of description, components in the drawings may be exaggerated or reduced in size. For example, the size and thickness of each configuration or arrangement as shown in the drawings may be arbitrarily shown for convenience of description, so embodiments of the present disclosure are not necessarily limited to those shown.

In the following embodiments, terms, such as "include" or "have" refer to that features or components as described in the specification exist and do not preclude the possibility that one or more other features or components may be added. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

If (e.g., when) one or more embodiments may be implemented differently, a specific process order may be performed differently from the order described. For example, two processes described consecutively may be performed substantially concurrently (e.g., simultaneously) or in the reverse order to that described.

In the following embodiments, if (e.g., when) a film, a region, a component, and/or the like is described as being "connected," this includes not only the case where the film, the region, the components, and/or the like are directly connected, but also the case where they are indirectly connected with other films, regions, components, and/or the like therebetween. For example, in the present disclosure, if (e.g., when) a film, a region, a component, and/or the like is described as being "electrically connected," this indicates cases where the film, the region, the component, and/or the like is directly electrically connected, and/or indirectly electrically connected with other films, regions, components, and/or the like therebetween.

In the following embodiments, the x-axis, y-axis, and z-axis are not limited to three axes in an orthogonal coordinate system, but may be interpreted in a broader sense including them. For example, the x-axis, y-axis, and z-axis may be orthogonal to each other or may refer to different directions that are not orthogonal to each other.

In the context of the present disclosure and unless otherwise defined, a plan view is an orthographic projection of a three-dimensional object from the position of a horizontal plane that intersects the object. For example, it is a top-down view, showing the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

Hereinafter, based on the above-described contents, a method of manufacturing a display apparatus and an electronic device including the display apparatus according to one or more embodiments will be described in more detail as follows.

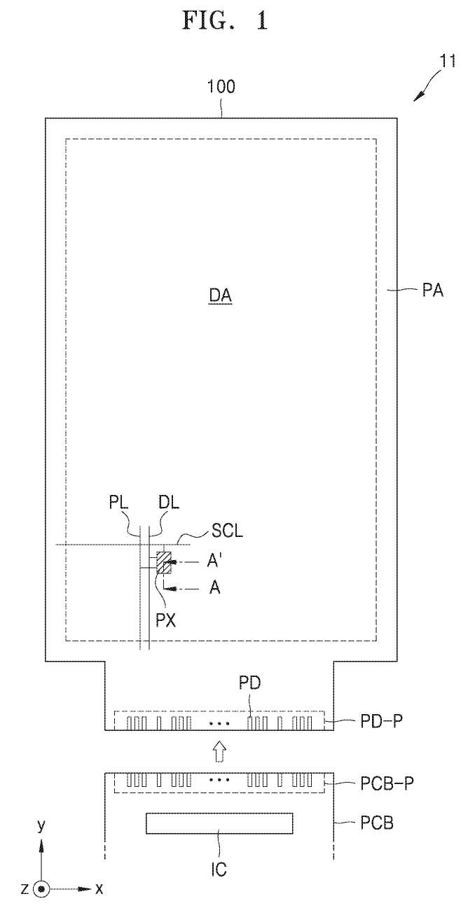

FIG. 1 is a plan view schematically illustrating a display apparatus according to one or more embodiments.

As illustrated in FIG. 1, a display apparatus 11 may include a display area DA and a peripheral area PA outside the display area DA. In FIG. 1, the display area DA is shown as having a rectangular shape (e.g., a substantially rectangular shape), but embodiments of the present disclosure are not limited to the rectangular shape of the display area DA. The display area DA may have other shapes, such as, for example, circular (e.g., substantially circular), elliptical (e.g., substantially elliptical), polygonal (e.g., substantially polygonal), or a specific (e.g., set or predetermined) geometric shape.

The display area DA may be a portion to display images and where a plurality of sub-pixels PX may be arranged. Each sub-pixel PX may include a display element, such as an organic light-emitting element. Each sub-pixel PX may be to emit light, for example, red, green, or blue light. The sub-pixels PX may be connected to a pixel circuit including a thin film transistor, a storage capacitor, and/or the like. The pixel circuit may be connected to a scan line SCL to transmit a scan signal, a data line DL that crosses the scan line SCL and transmits a data signal, and a driving voltage line PL to supply a driving voltage. For example, the data line DL and the driving voltage line PL may extend in the y-axis direction (hereinafter, referred to as a first direction), and the scan line SCL may extend in the x-axis direction (hereinafter, referred to as a second direction).

The sub-pixel PX may be to emit light having a luminance corresponding to an electrical signal received from the data line DL. The display area DA may be to display a set or predetermined image through light emitted from the sub-pixels PX. For reference, a sub-pixel PX may be defined as a light-emitting region that is to demit one selected from among red light, green light, and blue light.

The peripheral area PA may be an area where sub-pixels PX are not arranged and no images are displayed. A power supply wiring to drive the sub-pixels PX may be arranged in the peripheral area PA. Also, pads PD may be arranged in the peripheral area PA, and the peripheral area PA may include a pad area PD-P where the pads PD are arranged.

An integrated circuit (IC) device, such as a driver IC, may be mounted on a printed circuit board (PCB) that includes a driving circuit portion, and terminals electrically connected to the IC device may be arranged in a terminal area PCB-P of the PCB. The terminal area PCB-P may correspond to the pad area PD-P, and the pads PD as described in one or more embodiments may be electrically connected to terminals of the terminal area PCB-P in the peripheral area PA.

For reference, because the display apparatus 11 includes a substrate 100, the substrate 100 may also have the display area DA and the peripheral area PA. More details of the substrate 100 will be described in one or more embodiments.

Also, a plurality of transistors may be arranged in the display area DA. Depending on the type (kind) of transistor (e.g., a negative type (kind) (N-type (kind)) or a positive type (kind) (P-type (kind))) and/or operating conditions, a first terminal of the transistor may be a source electrode or a drain electrode, and a second terminal may be an electrode different from the first terminal among the source electrode and the drain electrode. For example, if (e.g., when) the first terminal is a source electrode, the second terminal may be a drain electrode.

Hereinafter, an organic light-emitting display apparatus will be described in more detail as an example of the display apparatus 11 according to one or more embodiments, but the display apparatus 11 of the present disclosure is not limited to the organic light-emitting display apparatus as described in one or more embodiments. In one or more embodiments, the display apparatus 11 of the present disclosure may be an inorganic light-emitting display or a display apparatus, such as a quantum dot light-emitting display. For example, an emission layer included in the display apparatus 11 may include an organic material and/or an inorganic material. In one or more embodiments, the display apparatus 11 may include an emission layer and quantum dots arranged on the path of light emitted from the emission layer.

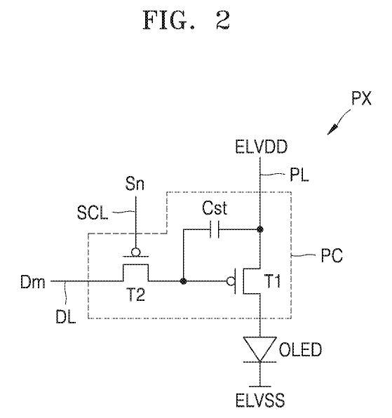

FIG. 2 is an example of an equivalent circuit diagram schematically illustrating a sub-pixel of the display apparatus 11 of FIG. 1. The equivalent circuit diagram of FIG. 2 is a basic equivalent circuit diagram, and at least one of suitably modified equivalent circuit diagrams applying the equivalent circuit diagram of FIG. 2 may be applied to a display apparatus according to one or more embodiments.

For convenience of description, a positive channel metal-oxide-semiconductor-type (kind) (pMOS-type (kind)) thin film transistor is illustrated in FIG. 2, but the pixel circuit disclosed in the present disclosure is not limited to the pMOS-type (kind) thin film transistor and may be suitably modified.

As illustrated in FIG. 2, each sub-pixel PX may include a pixel circuit PC connected to a scan line SCL and a data line DL and a light-emitting element OLED connected to the pixel circuit PC.

For example, the pixel circuit PC may include a first thin film transistor T1, a second thin film transistor T2, and a storage capacitor Cs. The second thin film transistor T2 may be connected to the scan line SCL and the data line DL and may be configured or arranged to transmit a data signal Dm input through the data line DL to the first thin film transistor T1 according to a scan signal Sn input through the scan line SCL.

For example, the first thin film transistor T1 may be a driving thin film transistor, and the second thin film transistor T2 may be a switching thin film transistor.

For example, the storage capacitor Cst may be connected to the second thin film transistor T2 and the driving voltage line PL and may be to store a voltage corresponding to the difference between the voltage received from the second thin film transistor T2 and a first power voltage ELVDD (or driving voltage) supplied to the driving voltage line PL.

For example, the first thin film transistor T1 may be connected to the driving voltage line PL and the storage capacitor Cst and may be to control a driving current flowing from the driving voltage line PL to the light-emitting element OLED in correspondence with the voltage value stored in the storage capacitor Cst. The light-emitting element OLED may be to emit light having a set or predetermined luminance according to the driving current.

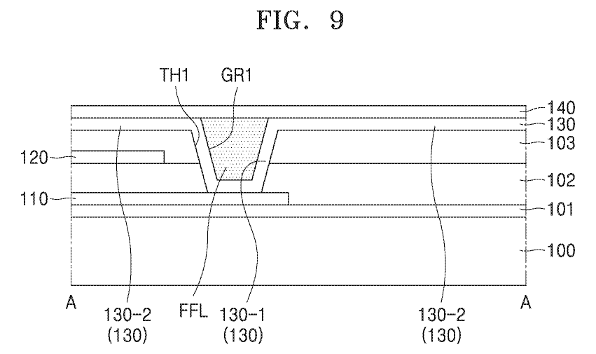

The light-emitting element OLED may be to receive a second power voltage ELVSS (or common voltage). For example, the light-emitting element OLED may be to receive the second power voltage ELVSS (or common voltage) through an opposite electrode 190 (cathode) (see FIG. 9), and the light-emitting element OLED may be to emit light having a set or predetermined luminance by a driving current according to a voltage difference between the first power voltage ELVDD (or driving voltage) and the second power voltage ELVSS (or common voltage).

With reference to FIG. 2, a case where the pixel circuit PC includes two thin film transistors and one storage capacitor Cst is described, but embodiments of the present disclosure are not limited to this specific pixel circuit configuration or arrangement. For example, the pixel circuit PC may include one or more capacitors and two or more thin film transistors.

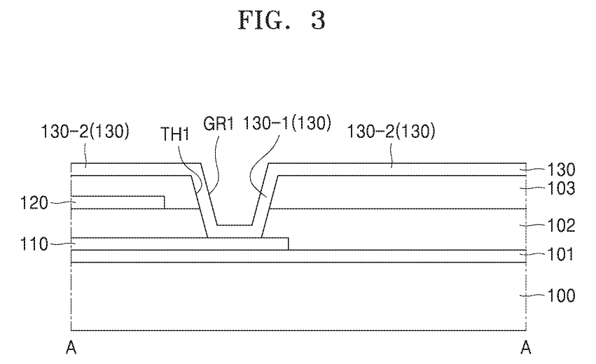

FIGS. 3 to 12 are cross-sectional views schematically illustrating a cross-section obtained along the line A-A' of FIG. 1 according to a manufacturing process sequence.

As illustrated in FIG. 3, the substrate 100 may include areas corresponding to the display area DA and the peripheral area PA outside the display area DA as described in one or more embodiments. The substrate 100 may include one or more suitable flexible or bendable materials.

For example, the substrate 100 may include glass, metal, and/or a polymer resin. Also, the substrate 100 may include polymer resins, such as polyethersulfone, polyacrylate, polyetherimide, polyethylene naphthalate, polyethylene terephthalate, polyphenylene sulfide, polyarylate, polyimide, polycarbonate, and/or cellulose acetate propionate.

For example, the substrate 100 may have a multilayer structure including two layers and a barrier layer between the two layers. The two layers each may include such polymer resin including an inorganic material, and the barrier layer may include an inorganic material (such as silicon oxide, silicon nitride, silicon oxynitride, and/or the like). In one or more embodiments, the substrate 100 may include inorganic materials, such as silicon oxide, silicon nitride, silicon oxynitride, and/or the like, and one or more suitable layers and components for screen display (for example, display elements utilizing organic light emission, display elements utilizing liquid crystal, and/or the like) may be arranged on the substrate 100 including the inorganic material.

A buffer layer 101 may be arranged on the substrate 100. The buffer layer 101 may be to serve as a barrier layer and/or a blocking layer to prevent diffusion (or reduce a degree or occurrence of diffusion) of impurity ions, prevent penetration of moisture and/or external air (or reduce a degree or occurrence of penetration of moisture and/or external air), and planarize the surface of the substrate 100. The buffer layer 101 may include silicon oxide, silicon nitride, and/or silicon oxynitride. Also, the buffer layer 101 may adjust the rate of heat provision during a crystallization process to form or arrange the semiconductor layer 110 so that the semiconductor layer 110 is uniformly (e.g., substantially uniformly) crystallized.

The semiconductor layer 110 may be arranged on the buffer layer 101. The semiconductor layer 110 may be made of polysilicon and may include a channel region with no doped impurities, and source and drain regions formed or arranged by impurity doping on both sides (e.g., two opposing sides) of the channel region. In one or more embodiments, the impurity may vary depending on the type (kind) of thin film transistor and may be N-type (kind) impurity and/or P-type (kind) impurity.

A gate insulating film 102 may be arranged on the semiconductor layer 110. The gate insulating film 102 may be an element to secure insulation (e.g., electrical insulation) between the semiconductor layer 110 and a gate layer 120. The gate insulating film 102 may include inorganic materials, such as silicon oxide, silicon nitride, and/or silicon oxynitride, and may be between the semiconductor layer 110 and the gate layer 120. Also, the gate insulating film 102 may be formed or arranged to correspond to the entire surface of the substrate 100 and may have a structure in which contact holes are formed or arranged in set or predetermined portions of the gate insulating film 102. As such, an insulating (e.g., electrically insulating) film including the inorganic material may be formed or arranged through chemical vapor deposition (CVD) and/or atomic layer deposition (ALD). The formation or arrangement of insulating (e.g., electrically insulating) films including inorganic materials through CVD and/or ALD may also be the case for one or more embodiments and variations thereof as described in more detail herein.

The gate layer 120 may be arranged on the gate insulating film 102. The gate layer 120 may be arranged at a position overlapping vertically with the semiconductor layer 110 and may include at least one metal selected from among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu).

An interlayer insulating film 103 may be arranged on the gate layer 120. The interlayer insulating film 103 may cover the gate layer 120. The interlayer insulating film 103 may be made of an inorganic material. For example, the interlayer insulating film 103 may be a metal oxide and/or a metal nitride, and, for example, the inorganic material may include silicon oxide (e.g., SiO_{X},wherein 0 < x ≤ 2; e.g., SiO₂), silicon nitride (e.g., Si₃N₄ or SiNₓ, wherein 0 < x ≤ 2), silicon oxynitride (e.g., Si₂N₂O or SiOₓN_{y}, wherein 0 < x ≤ 2 and 0 ≤ y ≤ 2; e.g., SiON), aluminum oxide (e.g., Al₂O₃), titanium oxide (e.g., TiOₓ, wherein 0 < x ≤ 2; e.g., TiO₂), tantalum oxide (e.g., Ta₂O₅), hafnium oxide (e.g., HfO₂), zinc oxide (e.g., ZnOₓ, wherein 0 < x ≤ 2; e.g., ZnO), and/or the like. The interlayer insulating film 103 may, in one or more embodiments, have a double structure of SiOₓ/SiN_{y} or SiNₓ/SiO_{y}.

Also, an additional gate layer and an additional interlayer insulating (e.g., electrically insulating) film may be between the gate layer 120 and the semiconductor layer 110 and may be applied to one or more embodiments. The additional gate layer may include substantially the same material as the gate layer 120 and may have substantially the same layer structure as the gate layer 120. The additional interlayer insulating film may include substantially the same material as the interlayer insulating film 103 and may have substantially the same layer structure as the interlayer insulating film 103.

For example, a method of manufacturing the display apparatus 11 may include forming or arranging a semiconductor layer 110 and a gate insulating film 102 and interlayer insulating film 103 on the semiconductor layer 110 on the substrate 100. The gate insulating film 102 and the interlayer insulating film 103 both as described in one or more embodiments may be referred to as a first insulating layer 102 and 103 for convenience of description. The first insulating layer 102 and 103 may have (or include) a first through hole TH1 exposing a top surface of the semiconductor layer 110 upward. For example, the method involves forming or arranging a semiconductor layer 110 and two insulating films (gate insulating film 102 and interlayer insulating film 103) on a substrate 100. These insulating films are collectively referred to as the first insulating layer 102 and 103. The first insulating layer includes a through hole TH1 that exposes the top surface of the semiconductor layer 110.

For example, the gate insulating film 102 and the interlayer insulating film 103, as described herein, may be referred to collectively as the first insulating layer 102 and 103 for convenience. The first insulating layer 102 and 103 may include a through hole TH1 that exposes the top surface of the semiconductor layer 110. This through hole TH1 may be formed or arranged by a through hole in the gate insulating film 102 and a through hole in the interlayer insulating film 103. For example, the first through hole TH1 may be substantially continuously formed or arranged by a through hole of the gate insulating film 102 and a through hole of the interlayer insulating film 103.

A first metal layer 130 may be formed or arranged on the first insulating layer 102 and 103. The first metal layer 130 may be arranged on the first insulating layer 102 and 103. The first metal layer 130 may directly contact a top surface of the first semiconductor layer 110 through the first through hole TH1.

The first metal layer 130 may include a metal material. The metal material may include one or more selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the first metal layer 130 may be a layer including molybdenum (Mo) or may include a layer including molybdenum (Mo).

For example, the method of manufacturing the display apparatus 11 may further include forming or arranging a first metal layer 130 including a first portion 130-1 covering an inner side surface of the first through hole TH1 and a top surface of the semiconductor layer 110, and a second portion 130-2 covering a top surface of the first insulating layer 102 and 103.

The first metal layer 130 may include a first portion 130-1 covering an inner side surface of the first through hole TH1 and a top surface of the semiconductor layer 110, and a second portion 130-2 covering a top surface of the first insulating layer 102 and 103 (or a top surface of the interlayer insulating film 103). A cross-section of the first portion 130-1 may have a shape corresponding to a shape of a cross-section of the first through hole TH1.

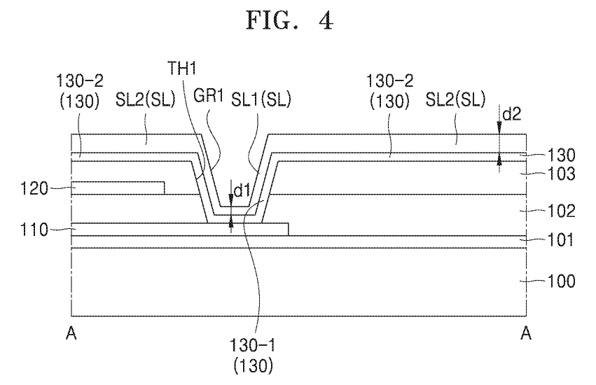

As illustrated in FIG. 4, a selection layer SL may be formed or arranged on the first metal layer 130. The selection layer SL may cover both (e.g., simultaneously) the first portion 130-1 and the second portion 130-2 of the first metal layer 130. The selection layer SL may be arranged on the first metal layer 130.

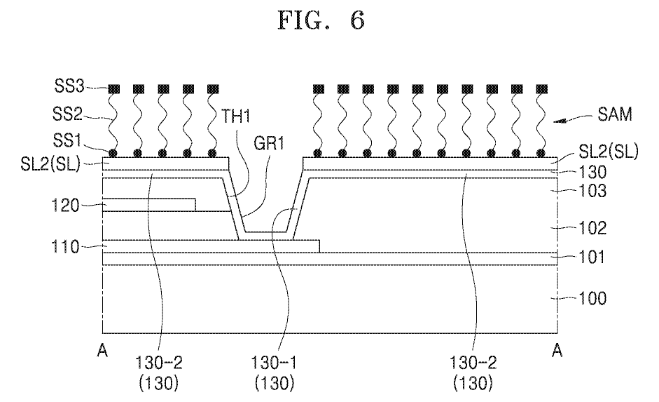

The selection layer SL may be an element to form or arrange a self-assembled monolayer (SAM in FIG. 6) to be described in more detail in one or more embodiments. For example, the selection layer SL may be formed or arranged at a position where the self-assembled monolayer SAM is to be formed or arranged. For the purpose of forming or arranging the self-assembled monolayer SAM at the desired or suitable position, after the selection layer SL is formed or arranged on the first metal layer 130, a portion of the selection layer SL may be removed. For example, a pattern may be formed or arranged on the selection layer SL.

For example, the selection layer SL may include a first region SL1 covering the first portion 130-1 of the first metal layer 130 and a second region SL2 covering the second portion 130-2 of the first metal layer 130. For example, the method of manufacturing the display apparatus 11 may further include forming or arranging a selection layer SL including a first region SL1 covering the first portion 130-1 and a second region SL2 covering the second portion 130-2. A thickness (d1 in FIG. 4, the same hereinafter) of the first region SL1 may be less than a thickness (d2 in FIG. 4, the same hereinafter) of the second region SL2. The thickness d2 of the second region SL2 may be greater than the thickness d1 of the first region SL1.

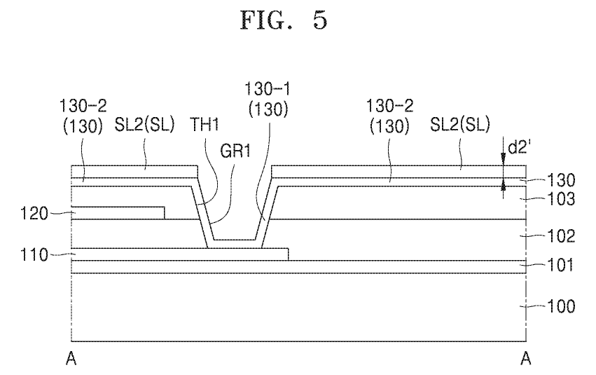

As illustrated in FIG. 5, the first region SL1 of the selection layer SL may be removed. For example, the method of manufacturing the display apparatus 11 may further include removing the first region SL1 of the selection layer SL. Due to the difference between the thickness d1 of the first region SL1 and the thickness d2 of the second region SL2 of the selection layer SL as described in one or more embodiments, even if (e.g., when) an etching process is applied to the entire selection layer SL, only the first region SL1 may be removed. For example, the etching process may be applied to the first region SL1 and the second region SL2 concurrently (e.g., simultaneously). As a result, the thickness of the second region SL2 may be different before and after the etching process. For example, the thickness d2 of the second region SL2 may become thinner after the etching process (or the operation of removing the first region SL1). For example, the thickness d2 of the second region SL2 before applying the etching process may be thicker than the thickness d2’ of the second region SL2 after applying the etching process.

For example, a dry etching process may be applied to the selection layer SL. The dry etching process may be applied to the entire selection layer SL, and because the thickness d1 of the first region SL1 is less than the thickness d2 of the second region SL2, the second region SL2 may remain and the first region SL1 may be removed. For example, the dry etching process may be applied to the first region SL1 and the second region SL2 concurrently (e.g., simultaneously). For example, the thickness d2 of the second region SL2 before applying the dry etching process may be thicker than the thickness d2’ of the second region SL2 after applying the dry etching process.

As illustrated in FIG. 6, a self-assembled monolayer SAM may be formed or arranged on the second region SL2. For example, the method of manufacturing the display apparatus 11 may further include forming or arranging a self-assembled monolayer SAM on the second region SL2.

The self-assembled monolayer SAM may be formed or arranged only on the selection layer SL remaining after the etching process. For example, the self-assembled monolayer SAM may include a head portion SS1 contacting the selection layer SL, a linker SS2 connected to the head portion SS1, and a terminal portion SS3 connected to the linker SS2. For example, the linker SS2 may be a plurality of alkyl chains. For example, if (e.g., when) the selection layer SL has hydrophilicity, the head portion SS1 may also have hydrophilicity. If (e.g., when) the selection layer SL has hydrophilicity, the terminal portion SS3 may have hydrophobicity. For example, if (e.g., when) the selection layer SL has hydrophobicity, the head portion SS1 may also have hydrophobicity. If (e.g., when) the selection layer SL has hydrophobicity, the terminal portion SS3 may have hydrophilicity. For example, the self-assembled monolayer SAM is formed only on the selection layer SL remaining after the etching process. The SAM includes the head portion SS1 that contacts the selection layer SL, the linker SS2 connected to the head portion SSI, and the terminal portion SS3 connected to the linker SS2. The linker SS2 may be composed of multiple alkyl chains. The head and terminal portions SS1 and SS3 of the SAM have hydrophilic or hydrophobic properties depending on the hydrophilicity or hydrophobicity of the selection layer SL.

By utilizing the self-assembled monolayer SAM with the selective surface modification approach as described in one or more embodiments, a filling material FFL may be formed or arranged at a precise position (e.g., a substantially precise position). Through a selective Atomic Layer Deposition (ALD) process, overall process reliability may be improved or enhanced and yield may be enhanced. For example, the selective ALD process allows for the deposition of thin films with atomic precision, ensuring uniform (e.g., substantially uniform) coverage and high-quality material properties. This precise control over film thickness and composition may significantly enhance the performance and durability of the display apparatus, leading to better device reliability and longer lifespan.

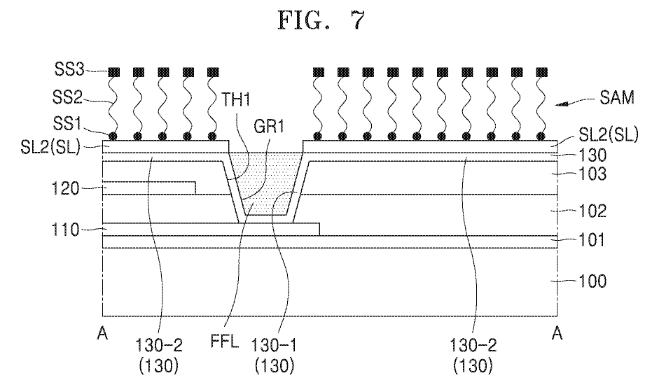

As illustrated in FIG. 7, a filling material FFL may be formed or arranged in a groove (GR1 in FIG. 6, the same hereinafter) defined by the second region SL2. For example, the method of manufacturing the display apparatus 11 may further include forming or arranging a filling material FFL in a groove GR1 defined by the second region SL2. For example, the forming or arranging of the filling material FFL in the groove GR1 may use an ALD process. If (e.g., when) the filling material FFL is formed or arranged by the ALD process, an amount of carbon contained in the filling material FFL may be less than 1%. In contrast, if (e.g., when) the filling material FFL is formed or arranged by a CVD process, an amount of carbon contained in the filling material FFL may be 3% or more and 5% or less.

The groove GR1 may be defined by a portion of the first metal layer 130 covering an inner side surface of the first through hole TH1 and a top surface of the semiconductor layer 110 exposed upward through the first through hole TH1. For example, the filling material FFL may be formed or arranged in an area where the selection layer SL and the self-assembled monolayer SAM are not present on the first metal layer 130, and the area where the selection layer SL and the self-assembled monolayer SAM are not present on the first metal layer 130 may be the groove GR1 as described in one or more embodiments.

The manufacturing process as illustrated in FIGS. 4 to 7 may be defined as a selective ALD process utilizing the selection layer SL and the self-assembled monolayer SAM. For example, utilizing the selection layer SL and the self-assembled monolayer SAM, the filling material FFL may be controlled or selected to be formed or arranged only in a desired or suitable area. If (e.g., when) the filling material FFL is formed or arranged by a selective ALD process, an amount of carbon contained in the filling material FFL may be less than 1%. In contrast, if (e.g., when) the filling material FFL is formed or arranged by a CVD process, an amount of carbon contained in the filling material FFL may be 3% or more and 5% or less.

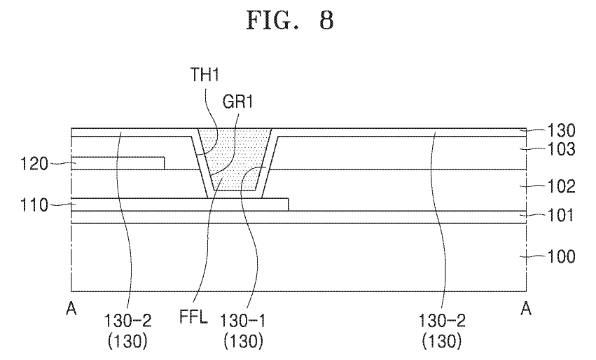

As illustrated in FIG. 8, the self-assembled monolayer SAM and the second region SL2 may be removed. According to one or more embodiments, the second region SL2 may be completely (e.g., substantially completely) removed or only partially removed. For example, at least a portion of the second region SL2 may be removed. For example, the method of manufacturing the display apparatus 11 may further include removing the self-assembled monolayer SAM and at least a portion of the second region SL2. As a result, a top surface of the first metal layer 130 may be exposed upward. A top surface of the filling material FFL and a top surface of the first metal layer 130 may form a substantially continuous surface.

As illustrated in FIG. 9, a second metal layer 140 may be arranged on the first metal layer 130 and the filling material FFL. For example, the method of manufacturing the display apparatus 11 may further include forming or arranging a second metal layer 140 on the first metal layer 130 and the filling material FFL.

The second metal layer 140 may include a metal material. The metal material may be one or more selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the second metal layer 140 may be a layer including molybdenum (Mo) or may include a layer including molybdenum (Mo).

For example, if (e.g., when) the selection layer SL includes an insulating (e.g., electrically insulating) material, the second region SL2 may be completely (e.g., substantially completely) removed in the operation of removing the self-assembled monolayer SAM and at least a portion of the second region SL2. As a result, if (e.g., when) the selection layer SL includes an insulating (e.g., electrically insulating) material, the second metal layer 140 may directly contact the first metal layer 130 after the second region SL2 (e.g., a portion of the second region SL2) is removed.

Through the direct contact between the first metal layer 130 and the second metal layer 140 after substantially complete removal of the selection layer SL, contact resistance (e.g., a degree or occurrence of contact resistance) may be reduced and electrical characteristics may be improved or enhanced by the structure including the second metal layer 140.

For example, if (e.g., when) the selection layer SL includes a conductive (e.g., electrically conductive) material, only a portion of the second region SL2 may be removed in the operation of removing the self-assembled monolayer SAM and at least a portion of the second region SL2. As a result, if (e.g., when) the selection layer SL includes a conductive (e.g., electrically conductive) material, the second metal layer 140 may be electrically connected to the first metal layer 130 through the second region SL2 of the selection layer SL.

For example, the self-assembled monolayer (SAM) and the second region (SL2) may be removed, either completely or partially. Regardless of whether all or just a portion of the second region is removed, all of the SAM is removed. This removal exposes the top surface of the first metal layer (130) and creates a substantially continuous surface with the filling material (FFL). Subsequently, a second metal layer (140) is formed on the first metal layer and the filling material. The second metal layer may include one or more suitable metals, such as aluminum, platinum, palladium, silver, magnesium, gold, nickel, neodymium, iridium, chromium, lithium, calcium, molybdenum, titanium, tungsten, and copper.

If (e.g., when) the selection layer (SL) is insulating, the second metal layer directly contacts the first metal layer after the second region is removed, reducing contact resistance and improving or enhancing electrical characteristics. If (e.g., when) the selection layer is conductive, only a portion of the second region may be removed, allowing the second metal layer to electrically connect to the first metal layer through the remaining second region.

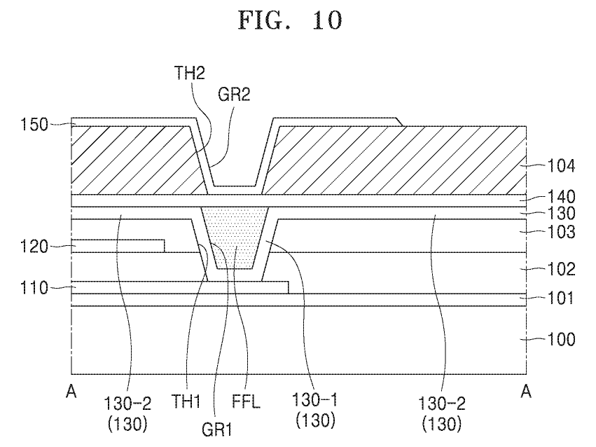

As illustrated in FIG. 10, an organic insulating layer 104 may be arranged on the second metal layer 140. The organic insulating layer 104 may be referred to as a second insulating (e.g., electrically insulating) layer in the present disclosure in the sense that the organic insulating layer 104 may be arranged on the first insulating layer 102 and 103 as described in one or more embodiments. For example, the method of manufacturing the display apparatus 11 may further include forming or arranging a second insulating (e.g., electrically insulating) layer on the second metal layer 140.

For example, the organic insulating layer 104 may be an organic insulating (e.g., electrically insulating) layer that covers the upper portion of the second metal layer 140 and has a generally or substantially flat top surface, serving as a planarization layer. The organic insulating layer 104 may include an organic material, such as acrylic, benzocyclobutene (BCB), and/or hexamethyldisiloxane (HMDSO). The organic insulating layer 104 may have one or more suitable modifications, such as being configured or arranged as a single layer or multiple layers.

The organic insulating layer 104 may have (or include) a second through hole TH2. In plan view, the second through hole TH2 may overlap the first through hole TH1. The second through hole TH2 may expose upward a top surface of the second metal layer 140 arranged below the organic insulating layer 104.

As illustrated in FIG. 10, a third metal layer 150 may be arranged on the organic insulating layer 104. For example, the method of manufacturing the display apparatus 11 may further include forming or arranging a third metal layer 150 on the organic insulating layer 104 (or the second insulating layer).

The third metal layer 150 may include a metal material. The metal material may be one or more metals selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the second metal layer 140 may be a layer including molybdenum (Mo) or may include a layer including molybdenum (Mo).

The third metal layer 150 may cover a portion of the top surface of the organic insulating layer 104. The third metal layer 150 may cover an inner side surface of the second through hole TH2. The third metal layer 150 may cover a top surface of the second metal layer 140 exposed upward by the second through hole TH2. As a result, the third metal layer 150 may directly contact the second metal layer 140 through the second through hole TH2. A second groove GR2 may be defined by the third metal layer 150 covering the inner side surface of the second through hole TH2 and the top surface of the second metal layer 140 exposed upward by the second through hole TH2.

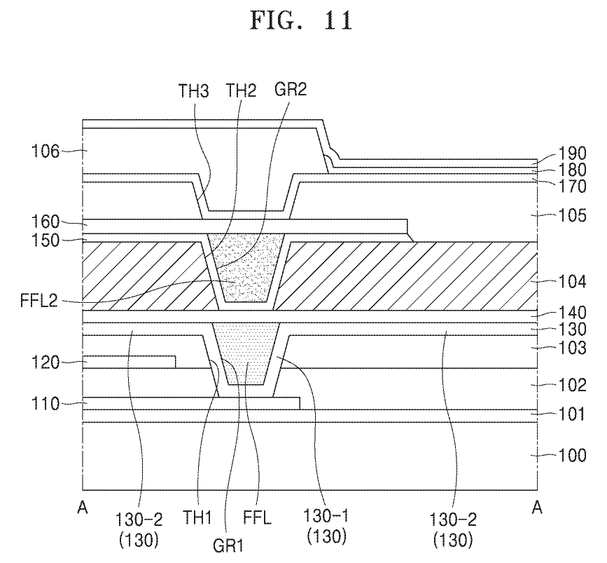

As illustrated in FIG. 11, a second filling material FFL2 may be formed or arranged in the second groove GR2 defined by the third metal layer 150. For example, the method of manufacturing the display apparatus 11 may further include forming or arranging a second filling material FFL2 in a second groove GR2 defined by the third metal layer 150 covering the inner side surface of the second through hole TH2 and the top surface of the second metal layer 140 exposed upward by the second through hole TH2. A top surface of the second filling material FFL2 and a top surface of the third metal layer 150 may form a substantially continuous surface.

As illustrated in FIG. 11, a fourth metal layer 160 may be arranged on the third metal layer 150 and the second filling material FFL2. For example, the method of manufacturing the display apparatus 11 may further include forming or arranging a fourth metal layer 160 on the third metal layer 150 and the second filling material FFL2.

A second organic insulating layer 105 may be arranged on the fourth metal layer 160. For example, the method of manufacturing the display apparatus 11 may form or arrange a second organic insulating layer 105 on the fourth metal layer 160. The second organic insulating layer 105 may cover at least a portion of the fourth metal layer 160. The second organic insulating layer 105 may have a third through hole TH3 exposing a portion of the top surface of the fourth metal layer 160 upward. In plan view, the third through hole TH3 may overlap with the second through hole TH2, but the position of the third through hole TH3 is not limited to overlapping with the second through hole TH2.

A pixel electrode 170 may be arranged on the second organic insulating layer 105. For example, the method of manufacturing the display apparatus 11 may further include forming or arranging a pixel electrode 170 on the second organic insulating layer 105.

The pixel electrode 170 may be electrically connected to the fourth metal layer 160 through the third through hole TH3 in the second organic insulating layer 105. The pixel electrode 170 may include a transparent (e.g., substantially transparent) conductive (e.g., electrically conductive) layer of a transparent (e.g., substantially transparent) conductive (e.g., electrically conductive) oxide, such as indium tin oxide (ITO), indium oxide (e.g., In₂O₃), and/or indium zinc oxide (IZO), and a reflective layer of a metal, such as Al and/or Ag. For example, the pixel electrode 170 may have a three-layer structure of ITO/Ag/ITO.

A pixel-defining layer 106 may be arranged on the pixel electrode 170 and arranged to cover the edges of the pixel electrode 170. The pixel-defining layer 106 may cover the edges of the pixel electrode 170. The pixel-defining layer 106 may have an opening corresponding to a pixel (PX in FIG. 1), and the opening may be formed or arranged so that at least the central portion of the pixel electrode 170 is exposed upward.

The pixel-defining layer 106 may include an organic material, such as polyimide and/or hexamethyldisiloxane (HMDSO). In one or more embodiments, the pixel-defining layer 106 may include an inorganic material. For example, the pixel-defining layer 106 may include at least one inorganic material selected from among silicon nitride, aluminum nitride, zirconium nitride, titanium nitride, hafnium nitride, tantalum nitride, silicon oxide, aluminum oxide, titanium oxide, tin oxide, and silicon oxynitride.

The pixel-defining layer 106 including an inorganic material may be thinner than a pixel-defining layer 106 including an organic material. Therefore, if (e.g., when) forming or arranging the pixel-defining layer 106 utilizing an inorganic material, a relatively thin pixel-defining layer 106 may be formed or arranged.

An intermediate layer 180 and an opposite electrode 190 may be arranged on the opening of the pixel-defining layer 106. The intermediate layer 180 may include a low molecular weight material and/or a high molecular weight material. If (e.g., when) the intermediate layer 180 includes a low molecular weight material, the intermediate layer 180 may include a hole injection layer, a hole transport layer, an emission layer, an electron transport layer, an electron injection layer, and/or the like. If (e.g., when) the intermediate layer 180 includes a high molecular weight material, the intermediate layer 180 may have a structure including a hole transport layer and an emission layer.

The opposite electrode 190 may include a transparent (e.g., substantially transparent) conductive (e.g., electrically conductive) layer of a transparent (e.g., substantially transparent) conductive (e.g., electrically conductive) oxide, such as ITO, In₂O₃, and/or IZO. The pixel electrode 170 may be utilized as an anode, and the opposite electrode 190 may be utilized as a cathode. However, the polarity of the electrodes may be the opposite thereto.

The structure of the intermediate layer 180 is not limited to the description herein and may be other structures. For example, at least one of the layers constituting the intermediate layer 180 may be formed or arranged integrally with the opposite electrode 190. As one or more embodiments, the intermediate layer 180 may include a patterned layer corresponding to each of a plurality of pixel electrodes 170.

For example, the opposite electrode 190 may be arranged above the display area DA and may be arranged on the entire surface of the display area DA. However, as described in one or more embodiments, the opposite electrode 190 in the present disclosure may be distinguished to correspond to each of the light-emitting regions.

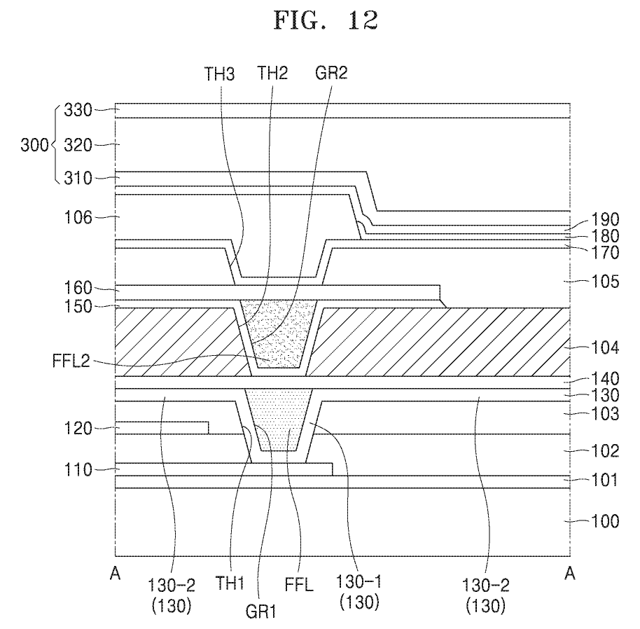

As illustrated in FIG. 12, a thin film encapsulation layer 300 may be arranged on the opposite electrode 190. For example, the method of manufacturing the display apparatus 11 may further include forming or arranging a thin film encapsulation layer 300 on the opposite electrode 190.

The thin film encapsulation layer 300 may cover the entire display area DA and may be arranged to extend toward the peripheral area PA to cover at least a portion of the peripheral area PA.

The thin film encapsulation layer 300 may extend to the outside of a common power supply line. The thin film encapsulation layer 300 may include a first encapsulation layer 310, a second encapsulation layer 320, and a third encapsulation layer 330, and the second encapsulation layer 320 may be between the first encapsulation layer 310 and the third encapsulation layer 330.

For example, the first encapsulation layer 310 and the third encapsulation layer 330 may be inorganic encapsulation layers. The first encapsulation layer 310 and the third encapsulation layer 330 may include one or more inorganic materials, such as aluminum oxide, titanium oxide, tantalum oxide, hafnium oxide, zinc oxide, silicon oxide, silicon nitride, and/or silicon oxynitride.

The first encapsulation layer 310 and the third encapsulation layer 330 may be a single layer or multiple layers including the materials as described in one or more embodiments. The first encapsulation layer 310 and the third encapsulation layer 330 may include substantially the same material or different materials from each other. The thickness of the first encapsulation layer 310 may be different from the thickness of the third encapsulation layer 330. The thickness of the first encapsulation layer 310 may be greater than the thickness of the third encapsulation layer 330. In one or more embodiments, the thickness of the third encapsulation layer 330 may be greater than the thickness of the first encapsulation layer 310, or the thickness of the first encapsulation layer 310 may be substantially the same as the thickness of the third encapsulation layer 330.

For example, the second encapsulation layer 320 may be an organic encapsulation layer. The second encapsulation layer 320 may include a monomer-based material and/or a polymer-based material. The polymer-based materials may include an acrylic resin, an epoxy resin, polyimide, and/or polyethylene. As one or more embodiments, the second encapsulation layer 320 may include acrylate.

A barrier wall may be located or arranged on the peripheral area PA of the substrate 100. The barrier wall may be arranged to be around (e.g., surround) the display area DA and may prevent a material that forms the second encapsulation layer 320 of the thin film encapsulation layer 300 from overflowing to the outside of the substrate 100 (or reduce a degree to or occurrence of which a material that forms the second encapsulation layer 320 of the thin film encapsulation layer 300 overflows to the outside of the substrate 100). Therefore, the second encapsulation layer 320 may contact the inner side surface of the barrier wall opposite to (e.g., facing) the display area DA. In one or more embodiments, the barrier wall 200 may include a plurality of barrier walls.

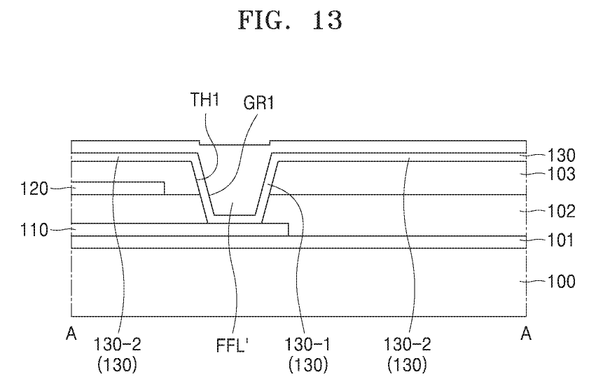

FIGS. 13 to 16 are cross-sectional views schematically illustrating a cross-section obtained along the line A-A' of FIG. 1 according to a manufacturing process sequence.

The manufacturing process of FIGS. 13 to 16 may replace the manufacturing process of FIGS. 4 to 9. For reference, descriptions that are substantially identical or overlap with the descriptions given herein with reference to FIGS. 13 to 16 may not be provided.

As illustrated in FIG. 13, an insulating material layer FFL' may be arranged on the first metal layer 130. The method of manufacturing the display apparatus 11 may further include forming or arranging an insulating material layer FFL' covering the first portion 130-1 and the second portion 130-2 of the first metal layer 130 utilizing an ALD process. If (e.g., when) the insulating material layer FFL' is formed or arranged by the ALD process, an amount of carbon contained in the insulating material layer FFL' may be less than 1%. In contrast, if (e.g., when) the insulating material layer FFL' is formed or arranged by a CVD process, an amount of carbon contained in the insulating material layer FFL' may be 3% or more and 5% or less.

For example, the insulating material layer FFL' may cover the first metal layer 130. A portion of the insulating material layer FFL' may fill the groove GR1, and the other portion of the insulating material layer FFL' may cover a top surface of the first metal layer 130 around the groove GR1.

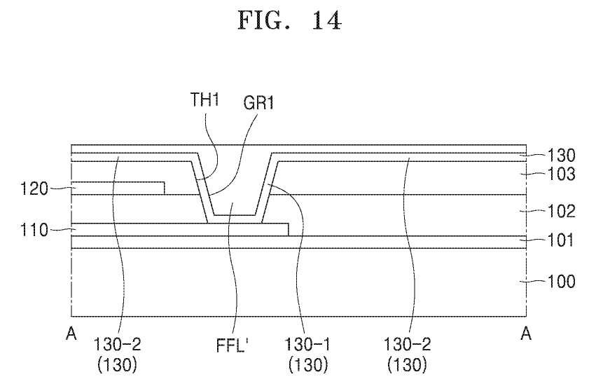

As illustrated in FIG. 14, a top surface of the insulating material layer FFL' may have a step (e.g., a protrusion) corresponding to a step of the first metal layer 130. For example, the method of manufacturing the display apparatus 11 may further include planarizing a top surface of the insulating material layer FFL' utilizing a Chemical Mechanical Polishing (CMP) process. The CMP process may remove the step on the top surface of the insulating material layer FFL'. For example, to address this step (e.g., this protrusion), the method of manufacturing the display apparatus 11 may include planarizing the top surface of the insulating material layer FFL' using the CMP process. The CMP process effectively or suitably removes the step (e.g., the protrusion) on the top surface of the insulating material layer FFL', resulting in a smooth and even surface.

Through the removal of surface steps by the CMP process, there may be an effect of improving or enhancing the reliability of the subsequent process and enhancing the yield by improving or enhancing the surface flatness.

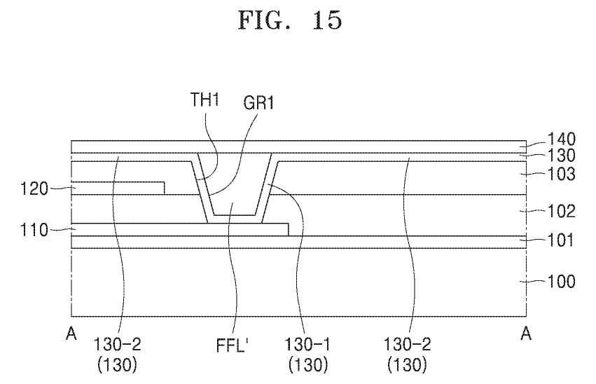

As illustrated in FIG. 15, a second metal layer 140 may be arranged on the insulating material layer FFL'. For example, the method of manufacturing the display apparatus 11 may further include forming or arranging a second metal layer 140 on the insulating material layer FFL'.

Before forming or arranging the second metal layer 140, the method of manufacturing the display apparatus 11 may apply an etching process (for example, a dry etching process) to the entire insulating material layer FFL' to reduce the thickness of the insulating material layer FFL'. As a result, the insulating material layer FFL' may be arranged only within the groove GR1, and the second metal layer 140 and the first metal layer 130 may directly contact each other.

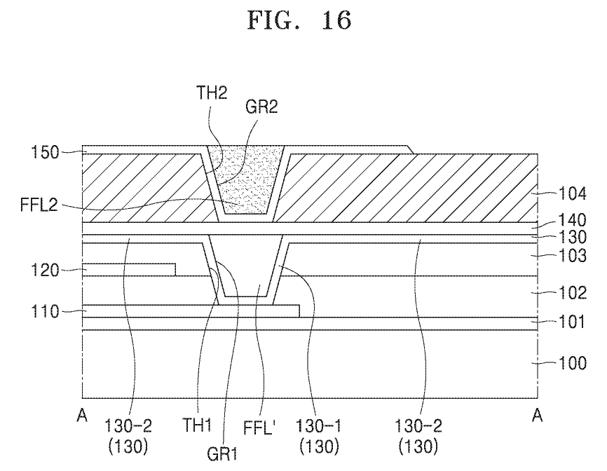

As illustrated in FIG. 16, a second insulating (e.g., electrically insulating) layer (referring to the organic insulating layer 104, the same hereinafter) may be arranged on the second metal layer 140, and a third metal layer 150 may be arranged on the second insulating layer. For example, the method of manufacturing the display apparatus 11 may further include forming or arranging a second insulating (e.g., electrically insulating) layer on the second metal layer 140 and forming or arranging a third metal layer 150 on the second insulating layer.

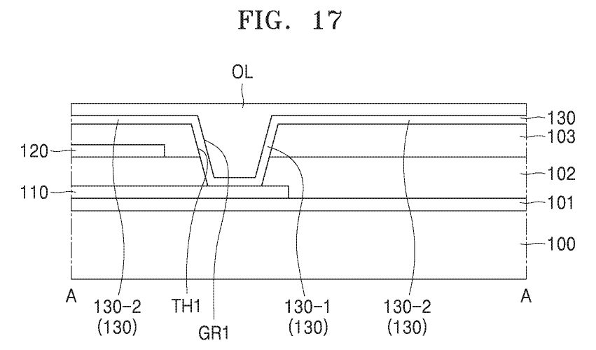

FIGS. 17 to 21 are cross-sectional views schematically illustrating a cross-section obtained along the line A-A' of FIG. 1 according to a manufacturing process sequence.

The manufacturing process of FIGS. 17 to 21 may replace the manufacturing process of FIGS. 4 to 9. For reference, descriptions that are substantially identical or overlap with the descriptions given herein with reference to FIGS. 17 to 21 may not be provided.

As illustrated in FIG. 17, an organic film OL may be arranged on the first metal layer 130. For example, the forming or arranging of a filling material FFL in a groove GR1 defined by the second region SL2 in the method of manufacturing the display apparatus 11 may include forming or arranging an organic film OL on the first metal layer 130. For example, the organic film OL may include an organic material, such as acrylic, BCB, and/or HMDSO.

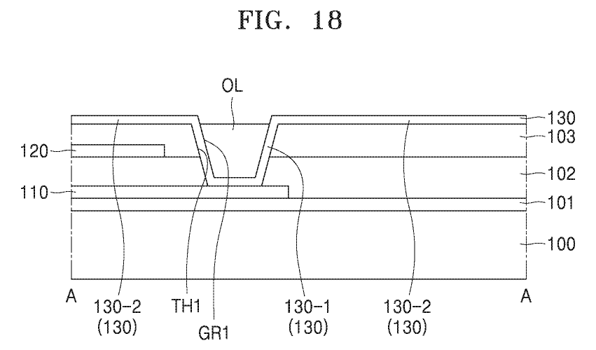

As illustrated in FIG. 18, a portion of the organic film OL on the second portion 130-2 may be removed. For example, the forming or arranging of a filling material FFL in a groove GR1 defined by the second region SL2 in the method of manufacturing the display apparatus 11 may further include removing a portion of the organic film OL on the second portion 130-2. In the removing of a portion of the organic film OL on the second portion 130-2, the thickness of the portion of the organic film OL in the groove GR1 may be reduced. For example, the portion of the organic film OL in the groove GR1 may be etched concurrently (e.g., simultaneously) with the portion of the organic film OL on the second portion 130-2. However, the portion of the organic film OL in the groove GR1 may remain in the groove GR1.

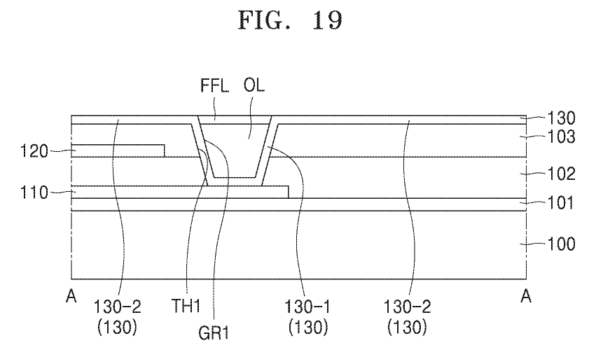

As illustrated in FIG. 19, the filling material FFL may be arranged on the organic film OL remaining in the groove GR1. The filling material FFL may be formed by applying the manufacturing process of FIGS. 4 to 7. For example, the filling material FFL on the organic film OL remaining in the groove GR1 may be formed by a selective ALD process utilizing the selection layer SL and the self-assembled monolayer SAM. If (e.g., when) the filling material FFL is formed by a selective ALD process, an amount of carbon contained in the insulating material layer FFL' may be less than 1%. In contrast, if (e.g., when) the insulating material layer FFL' is formed by a CVD process, an amount of carbon contained in the insulating material layer FFL' may be 3% or more and 5% or less.

For example, the selection layer SL may be formed or arranged to cover the top surface of the organic film OL and to cover the first metal layer 130 not covered by the organic film OL. Subsequently, the portion of the selection layer SL covering the organic film OL may be removed. If (e.g., when) the portion of the selection layer SL covering the organic film OL is removed, the selection layer SL may expose the top surface of the organic film OL upward. Subsequently, a self-assembled monolayer SAM may be formed or arranged on the selection layer SL, and a filling material FFL may be filled in an area where the self-assembled monolayer SAM is not formed or arranged.

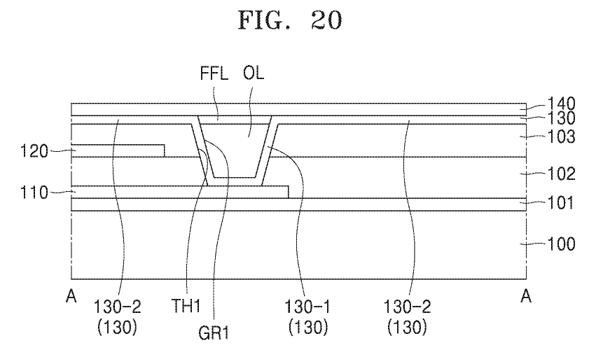

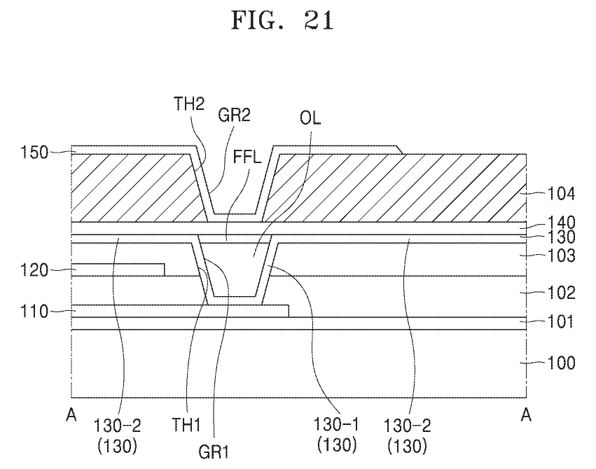

As illustrated in FIG. 20, a second metal layer 140 may be formed or arranged on the first metal layer 130. The second metal layer 140 may be arranged on a top surface of the filling material FFL. As illustrated in FIG. 21, a second insulating (e.g., electrically insulating) layer may be formed or arranged on the second metal layer 140, and a third metal layer 150 may be formed or arranged on the second insulating layer.

Hereinafter, based on the contents as described in one or more embodiments, an electronic device including a display apparatus according to one or more embodiments will be described in more detail as follows.

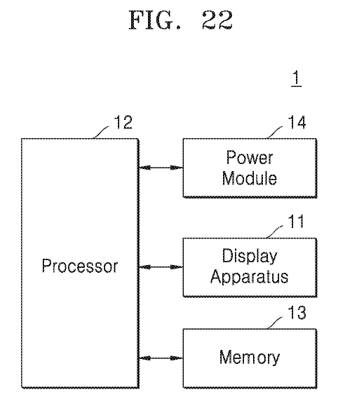

FIG. 22 is a block diagram of an electronic device according to one or more embodiments.

Referring to FIG. 22, an electronic device 1 according to one or more embodiments may include a display apparatus 11, a processor 12, a memory 13, and a power module 14.

The processor 12 may include at least one selected from among a central processing unit (CPU), an application processor (AP), a graphics processing unit (GPU), a communication processor (CP), an image signal processor (ISP), and a controller.

The memory 15 may be to store data information desired or necessary for the operation of the processor 12 or the display apparatus 11. If (e.g., when) the processor 12 executes an application stored in the memory 15, video data signals and/or input control signals may be transmitted to the display apparatus 11, and the display apparatus 11 may process the provided signals to output video information on a display screen.

The power module 14 may include a power supply module, such as a power adapter and/or a battery device, and a power conversion module that is to convert power supplied by the power supply module to generate power desired or necessary for the operation of the electronic device 1.

At least one of the components of the electronic device 1 as described in one or more embodiments may be included in the display apparatus according to one or more embodiments as described herein. Also, one or more of the individual modules included in one module functionally may be included in the display apparatus, and other parts may be provided separately from the display apparatus. For example, the display apparatus may include the display apparatus 11, and the processor 12, the memory 13, and the power module 14 may be provided in the form of other devices within the electronic device 1 that are not the display apparatus.

The display apparatus 11 in FIG. 22 may refer to one of the examples of the display apparatus 11 as described with reference to FIGS. 1 to 21. For convenience of description, other explanations may not be provided, but those skilled in the art can easily and clearly understand the display apparatus 11 of FIG. 22 from the description of FIGS. 1 to 21.

In one or more embodiments, the electronic device 1 may include a memory 13 that is to store data information, a processor 12 that is to generate data signals and/or control signals based on the data information, and a display apparatus 11 that is to operate based on the data signals and/or control signals. The display apparatus 11 may be a display apparatus manufactured by the manufacturing method of FIGS. 1 to 21.

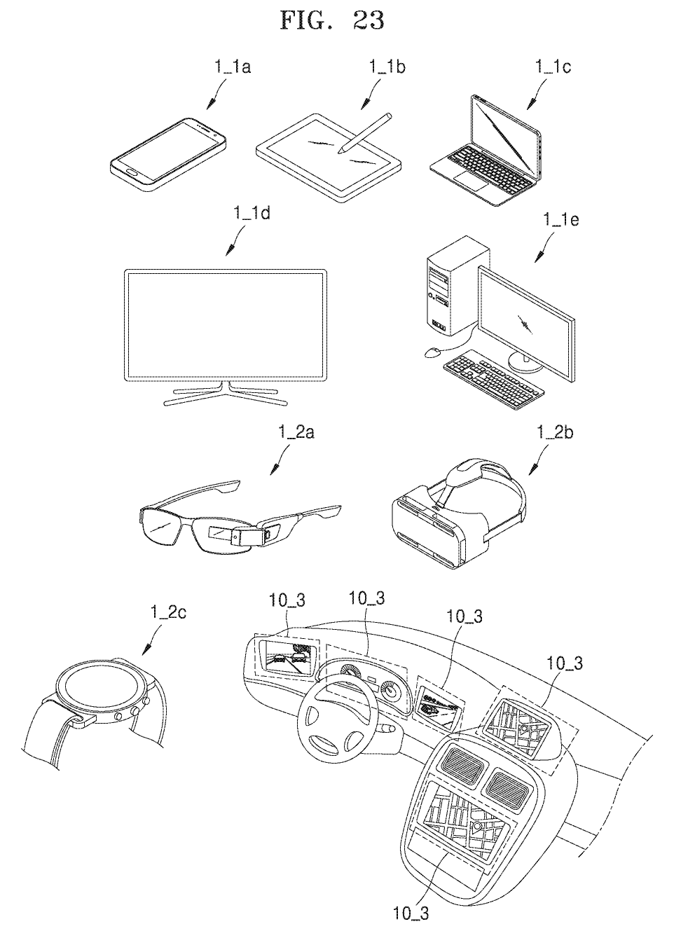

FIG. 23 is a schematic diagram of electronic devices according to one or more embodiments.

Referring to FIG. 23, one or more suitable electronic devices to which the display apparatus according to one or more embodiments is applied may include not only electronic devices to display images, such as a smartphone 1_1a, a tablet PC 1_1b, a laptop 1_1c, a TV 1_1d, a desktop monitor 1_1e, and/or the like, but also wearable electronic devices including a display apparatus, such as smart glasses 1_2a, a head-mounted display 1_2b, a smart watch 1_2c, and/or the like, and a vehicle electronic device 10_3 including a display apparatus, such as an instrument panel, a center fascia, a Center Information Display (CID) on a dashboard, a room mirror display, and/or the like of a vehicle.

According to one or more embodiments, a display apparatus in which an ultra-high resolution screen may be implemented, a method of manufacturing the display apparatus, and an electronic device including the display apparatus may be implemented. However, the scope of the present disclosure is not limited by the examples or exemplary terms unless otherwise claimed.

The present disclosure has been described with reference to one or more embodiments as illustrated in the drawings, but this is merely examples, and those skilled in the art will understand that one or more suitable modifications and other equivalent embodiments are possible therefrom. Therefore, the scope of the present disclosure should be determined by the appended claims and equivalents thereof.

It should be understood that embodiments described herein should be considered in a descriptive sense only and not for purposes of limitation. Descriptions of features or aspects within each embodiment should be considered as available for other similar features or aspects in one or more embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A method comprising:
forming a semiconductor layer and a first insulating layer on the semiconductor layer on a substrate, wherein the first insulating layer comprises a first through hole exposing a top surface of the semiconductor layer;
forming a first metal layer, wherein the first metal layer comprises a first portion covering an inner side surface of the first through hole and the top surface of the semiconductor layer, and a second portion covering a top surface of the first insulating layer;
forming a selection layer, wherein the selection layer comprises a first region covering the first portion and a second region covering the second portion;
removing the first region of the selection layer;
forming a self-assembled monolayer on the second region of the selection layer;
forming a filling material in a groove defined by the second region;
removing the self-assembled monolayer and at least a portion of the second region; and
forming a second metal layer on the first metal layer and the filling material,
wherein the method is a method of manufacturing a display apparatus.

2. The method as claimed in claim 1,
wherein a thickness of the second region is greater than a thickness of the first region.

3. The method as claimed in claim 2,
wherein the removing of the first region utilizes a dry etching process.

4. The method as claimed in claim 3,
wherein the dry etching process is applied to the first region and the second region concurrently.

5. The method as claimed in claim 4,
wherein a thickness of the second region before applying the dry etching process is greater than a thickness of the second region after the applying of the dry etching process.

6. The method as claimed in claim 1,
wherein the forming of the filling material in the groove defined by the second portion utilizes an Atomic Layer Deposition (ALD) process.

7. The method as claimed in claim 1,
wherein the selection layer comprises an insulating material.

8. The method as claimed in claim 7,
wherein after the at least a portion of the second region is removed, the first metal layer directly contacts the second metal layer.

9. The method as claimed in claim 1,
wherein the selection layer comprises a conductive material.

10. The method as claimed in claim 9,
wherein, in the removing of the self-assembled monolayer and the at least a portion the second region, only a portion of the second region is removed.

11. The method as claimed in claim 1,
further comprising forming a second insulating layer on the second metal layer,
wherein the second insulating layer comprises a second through hole overlapping with the first through hole in plan view.

12. The method as claimed in claim 11,
further comprising forming a third metal layer on the second insulating layer.

13. The method as claimed in claim 1,
wherein the forming of the filling material in the groove defined by the second region comprises:
forming an organic film on the first metal layer; and
removing a portion of the organic film on the second portion.

14. The method as claimed in claim 1,
wherein an amount of carbon contained in the filling material is less than 1%.

15. A method comprising:
forming a semiconductor layer and a first insulating layer on the semiconductor layer on a substrate, wherein the first insulating layer comprises a first through hole exposing a top surface of the semiconductor layer;
forming a first metal layer, wherein the first metal layer comprises a first portion covering an inner side surface of the first through hole and the top surface of the semiconductor layer, and a second portion covering a top surface of the first insulating layer;
forming an insulating material layer covering the first portion and the second portion utilizing an Atomic Layer Deposition (ALD) process;
planarizing a top surface of the insulating material layer utilizing a Chemical Mechanical Polishing (CMP) process; and
forming a second metal layer on the insulating material layer,
wherein the method is a method of manufacturing a display apparatus.

16. The method as claimed in claim 15, further comprising:
forming a second insulating layer comprising a second through hole overlapping with the first through hole in plan view on the second metal layer.

17. The method as claimed in claim 16, further comprising:
forming a third metal layer on the second insulating layer.

18. The method as claimed in claim 15,
wherein an amount of carbon contained in the insulating material layer is less than 1%.

19. A display apparatus manufactured by the method of claim 1.

20. An electronic device comprising:
a memory to store data information;
a processor to generate data signals and/or control signals based on the data information; and
a display apparatus to operate based on the data signals and/or control signals,
wherein the display apparatus is manufactured by the method as claimed in claim 1.
